(19) United States
(12) Patent Application Publication
(10) Pub. No.: US 2021/0066341 A1
(43) Pub. Date: Mar. 4, 2021

(54) SEMICONDUCTOR MEMORY DEVICE AND METHOD OF MANUFACTURING THE SAME

(71) Applicant: SK hynix Inc., Gyeonggi-do (KR)

(72) Inventors: Tae Hong GWON, Gyeonggi-do (KR); Jin Ho BIN, Gyeonggi-do (KR); Il Young KWON, Seoul (KR)

(21) Appl. No.: 16/809,730

(22) Filed: Mar. 5, 2020

(30) Foreign Application Priority Data
Sep. 3, 2019 (KR) 10-2019-0109139

(51) Int. Cl. H01L 27/11582; H01L 29/10; H01L 21/8234

(52) U.S. Cl. CPC H01L 27/11582; H01L 21/823412; H01L 29/1037

(57) ABSTRACT

The present technology includes a semiconductor memory device and a method of manufacturing the same. The semiconductor memory device includes a first stack including a first hole, a second stack provided on the first stack and including a second hole connected to the first hole, a first memory film formed along an inner sidewall of the first hole, a second memory film formed along an inner sidewall of the second hole, and a channel film formed along an inner sidewall of the first memory film and an inner sidewall of the second memory film. The channel film is a single, continuous element.

### CROSS-REFERENCE TO RELATED APPLICATION

The present application claims priority under 35 U.S.C. § 119(a) to Korean patent application number 10-2019-0109139, filed on Sep. 3, 2019, which is incorporated herein by reference in its entirety.

### BACKGROUND

### Field of Invention

The present disclosure relates to a semiconductor memory device and a method of manufacturing the same, and more particularly, to a three-dimensional semiconductor memory device and a method of manufacturing the same.

### Description of Related Art

A semiconductor memory device includes memory cells capable of storing data.

According to the method employed for storing and maintaining data, a semiconductor memory device may be classified into a volatile semiconductor memory device or a non-volatile semiconductor memory device. A volatile semiconductor memory device is a memory device in which stored data is lost when power supply is interrupted, and a non-volatile semiconductor memory device is a memory device in which stored data is maintained even though power supply is interrupted.

Recently, as use of portable electronic devices increases, demand for non-volatile semiconductor memory devices having higher integration, larger capacity, improved portability, and improved performance. For achieving these goals various three-dimensional semiconductor memory devices have been proposed and are under development.

### SUMMARY

Embodiments of the present disclosure provide a semiconductor memory device and a method of manufacturing the same capable of improving operation reliability.

A semiconductor memory device according to an embodiment of the present disclosure may include a first stack including a first hole, a second stack provided on the first stack and including a second hole connected to the first hole, a first memory film formed along an inner sidewall of the first hole, a second memory film formed along an inner sidewall of the second hole, and a channel film formed along an inner sidewall of the first memory film and an inner sidewall of the second memory film. The channel film may have an integrated structure.

A semiconductor memory device according to an embodiment of the present disclosure may include a first stack, a second stack provided on the first stack, a first hole passing through the first stack in a vertical direction, a first blocking film and a first storage film sequentially formed along an inner sidewall of the first hole, a second hole passing through the second stack in the vertical direction, a second blocking film and a second storage film sequentially formed along an inner sidewall of the second hole, a tunnel film formed along an inner sidewall of the first storage film and an inner sidewall of the second storage film, and a channel film formed in the tunnel film.

A method of manufacturing a semiconductor memory according to an embodiment of the present disclosure may include forming a first stack including a first hole, forming a first memory film and a channel sacrificial pattern in the first hole, forming a second stack including a second hole, on the first stack, forming a first preliminary memory film along an inner sidewall of the second hole, removing the channel sacrificial pattern exposed through the second hole, and forming a channel film in the first hole from which the channel sacrificial pattern is removed and in the second hole.

The semiconductor memory device according to embodiments of the present technology may provide the channel film passing through a plurality of cell stacks. Therefore, operation reliability of the semiconductor memory device according to embodiments of the present technology may be improved.

### BRIEF DESCRIPTION OF THE DRAWINGS

FIG. 1 is a perspective view schematically illustrating a semiconductor memory device according to an embodiment of the present disclosure.

FIG. 2A is a cross-sectional view of a semiconductor memory device according to an embodiment of the present disclosure.

FIG. 2B is an enlarged view of an A region of FIG. 2A.

FIGS. 3A to 3G are cross-sectional views describing a method of manufacturing the semiconductor memory device according to FIGS. 2A and 2B.

FIG. 4A is a cross-sectional view of a semiconductor memory device according to an embodiment of the present disclosure.

FIG. 4B is an enlarged view of a B region of FIG. 4A

FIGS. 5A to 5G are cross-sectional views illustrating a method of manufacturing the semiconductor memory device according to FIGS. 4A and 4B.

FIG. 6A is a cross-sectional view of a semiconductor memory device according to an embodiment of the present disclosure.

FIG. 6B is an enlarged view of a C region of FIG. 6A.

FIG. 7 is a cross-sectional view of a semiconductor memory device according to an embodiment of the present disclosure.

FIG. 8 is a cross-sectional view of a semiconductor memory device according to an embodiment of the present disclosure.

FIG. 9 is a cross-sectional view of a semiconductor memory device according to an embodiment of the present disclosure.

FIG. 10 is a block diagram illustrating a configuration of a memory system according to an embodiment of the present disclosure.

FIG. 11 is a block diagram illustrating a configuration of a computing system according to an embodiment of the present disclosure.

### DETAILED DESCRIPTION

The technical spirit of the present disclosure may be variously changed by being configured with embodiments having various aspects. Hereinafter, some embodiments of the present disclosure will be described in order to facilitate a person skilled in the art to which the present disclosure pertains to easily carry out the technical spirit of the present disclosure.

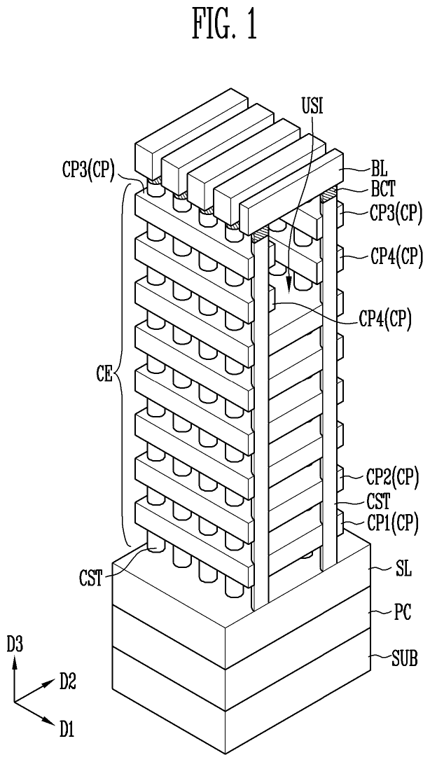

FIG. 1 is a perspective view schematically illustrating a semiconductor memory device according to an embodiment of the present disclosure.

Referring to FIG. 1, the semiconductor memory device may include a substrate SUB, a peripheral circuit structure PC on the substrate SUB, and a memory cell array on the peripheral circuit structure PC.

The substrate SUB may be a single crystal semiconductor film. For example, the substrate SUB may be a bulk silicon substrate, a silicon-on-insulator substrate, a germanium substrate, a germanium-on-insulator substrate, or a silicon-germanium substrate. The single crystal semiconductor film may be an epitaxial thin film formed through a selective epitaxial growth method on a semiconductor substrate.

The peripheral circuit structure PC may include NMOS transistors, PMOS transistors, a resistor, and a capacitor electrically connected to a memory cell array. The NMOS transistors, the PMOS transistors, the resistor, and the capacitor may be used as elements configuring a row decoder, a column decoder, a page buffer circuit, and an input/output circuit.

The peripheral circuit structure PC may be disposed between the memory cell array and the substrate SUB. For example, the memory cell array may overlap the peripheral circuit structure PC vertically (that is, in a third direction D3). The third direction D3 may be a direction perpendicular to an upper surface of the substrate SUB. When the memory cell array is disposed on the peripheral circuit structure PC, the area of the substrate SUB occupied by the memory cell array and the peripheral circuit structure PC may be reduced. Differently from the shown embodiment, the peripheral circuit structure PC may not overlap the memory cell array. In other words, the peripheral circuit structure PC and the memory cell array may be spaced apart in a plane (that is, in a first direction D1 or a second direction D2). The first direction D1 may be a direction parallel to the upper surface of the substrate SUB. The second direction D2 may be a direction parallel to the upper surface of the substrate SUB and perpendicular to the first direction D1.

The memory cell array may include a source film SL, bit lines BL, a stack CE, channel structures CST, and bit line contacts BCT.

The source film SL may be used as a source line and may be provided on the peripheral circuit structure PC. The source film SL may be a doped semiconductor film including a source dopant. For example, the source dopant may be an n-type dopant. For example, the source film SL may be formed by depositing the doped semiconductor film on the peripheral circuit structure PC. In an embodiment, a semiconductor film such as a silicon film may be deposited on the peripheral circuit structure using any suitable deposition method and then an n-type dopant may be implanted in the film to form the doped semiconductor film SL. For example, the doped semiconductor film may include doped silicon.

The stack CE may be provided on the source film SL. The stack CE may include conductive patterns CP and insulating patterns (not shown). The conductive patterns CP and the insulating patterns may be alternately arranged along the third direction D3. In other words, the conductive patterns CP and the insulating patterns may be alternately stacked along the third direction D3. For example, the conductive patterns CP may be formed of a gate conductive film. For example, the gate conductive film may include at least one of a doped silicon film, a metal silicide film, tungsten, nickel, and cobalt, and may be used as a word line connected to a memory cell or a select line connected to a select transistor. The conductive patterns CP may further include a barrier film surrounding the gate conductive film. For example, the barrier film may include at least one of titanium nitride and tantalum nitride. For example, the insulating patterns may include silicon oxide.

The conductive pattern CP disposed closest to the source film SL may be defined as a first conductive pattern CP1. The conductive pattern CP adjacent to the first conductive pattern CP1 may be defined as a second conductive pattern CP2.

The conductive patterns CP disposed furthest from the source film SL may be defined as third conductive patterns CP3. The third conductive patterns CP3 may be spaced apart from each other in the second direction D2 by an upper slit USI. The conductive patterns CP adjacent to the third conductive patterns CP3 may be defined as fourth conductive patterns CP4. The fourth conductive patterns CP4 may be spaced apart from each other in the second direction D2 by the upper slit USI. The upper slit USI may vertically overlap the conductive patterns CP except for the third and fourth conductive patterns CP3 and CP4.

For example, the first and second conductive patterns CP1 and CP2 may be used as source select lines, and the third and fourth conductive patterns CP3 and CP4 may be used as drain select lines. However, the present disclosure is not limited thereto. Conductive patterns disposed between the source select lines and the drain select lines may be used as word lines.

The channel structures CST may extend in the third direction D3 and pass through the stack CE. A plurality of channel structures CST passing through one third conductive pattern CP3 may be arranged in the first direction D1. A plurality of channel structures CST electrically connected to one bit line BL may be arranged in the second direction D2. The channel structures CST may be in direct contact with the source film SL. The channel structures CST may be electrically connected to the source film SL.

The bit lines BL may be provided on the stack CE. The bit lines BL may extend in the second direction D2. The bit lines BL may be arranged to be spaced apart from each other in the first direction D1. The bit lines BL may be electrically connected to the channel structures CST via bit line contacts BCT. The bit lines BL may include a conductive material. For example, the bit lines BL may include tungsten, aluminum, or copper.

The bit line contacts BCT may be provided between the bit lines BL and the channel structures CST. Each of the bit line contacts BCT may electrically connect one bit line BL to one channel structure CST. The bit line contacts BCT may include a conductive material. For example, the bit line contacts BCT may include tungsten, aluminum, or copper.

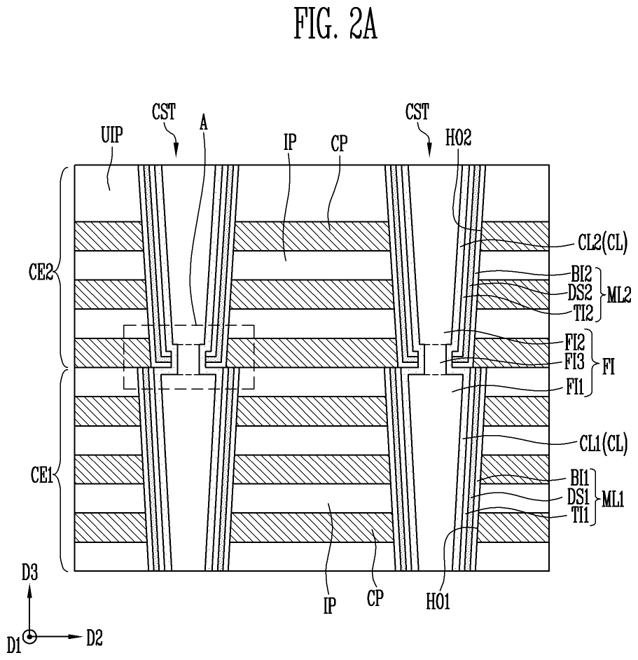

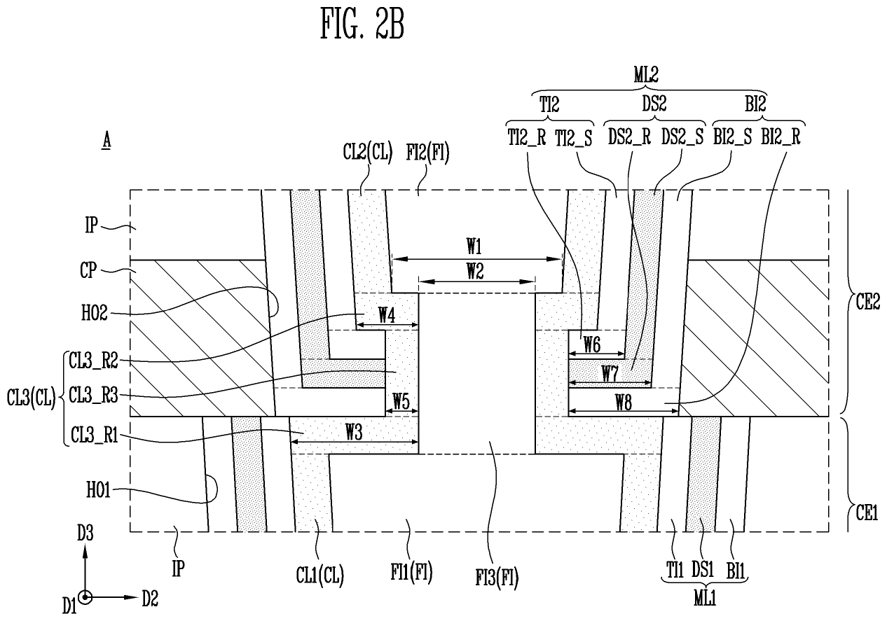

FIG. 2A is a cross-sectional view of a semiconductor memory device according to an embodiment of the present disclosure. FIG. 2B is an enlarged view of an A region of FIG. 2A.

The semiconductor memory device according to the present embodiment may be similar to the semiconductor memory device according to FIG. 1 except as described below.

Referring to FIGS. 2A and 2B, the semiconductor memory device according to the present embodiment may include a first stack CE1 and a second stack CE2. The first stack CE1 may be provided on the source film SL (refer to FIG. 1), and the second stack CE2 may be provided on the first stack CE1. The first stack CE1 may include conductive patterns CP and insulating patterns IP that are alternately stacked. The second stack CE2 may include an upper insulating pattern UIP, and conductive patterns CP and insulating patterns IP, that are alternately stacked. For example, the upper insulating pattern UIP may include silicon oxide.

The first stack CE1 may include first holes HO1. The first holes HO1 may pass through the first stack CE1. The second stack CE2 may include second holes HO2. The second holes HO2 may pass through the second stack CE2. The first holes HO1 may pass through the conductive patterns CP and the insulating patterns IP of the first stack CE1, and the second holes HO2 may pass through the conductive patterns CP, the insulating patterns IP, and the upper insulating pattern UIP of the second stack CE2. The second holes HO2 may vertically overlap with respective first holes HO1. Corresponding first holes HO1 and second holes HO2 may be connected to each other.

The channel structures CST may each completely fill corresponding first and second holes HO1 and HO2 connected to each other. Each of the channel structures CST may include a first memory film ML1 formed along an inner sidewall of the first hole HO1, a second memory film ML2 formed along an inner sidewall of the second hole HO2. Each of the channel structures CST may also include a channel film CL formed along an inner sidewall of the first memory film ML1 and an inner sidewall of the second memory film ML2. The channel film CL may be formed in a pillar or cylinder shape. When the channel film CL is formed in the pillar shape, the channel film CL may be filled in the first and second memory films ML1 and ML2 formed in a cylinder shape. When the channel film CL is formed in a cylinder shape, the channel structures CST may further include a filling film FI in the channel film CL. In the present embodiment, a structure in which the first and second memory films ML1 and ML2, the channel film CL, and the filling film FI are included in the channel structures CST will be described as an example.

The filling film FI may include a lower portion FI1 in the first stack CE1, an upper portion FI2 in the second stack CE2, and a filling connection portion FI3 connecting the lower portion FI1 and the upper portion FI2 to each other. The lower portion FI1 may be formed in the first hole HO1. The upper portion FI2 may be formed in the second hole HO2. The filling connection portion FI3 may be disposed at the same level as a boundary of the first and second stacks CE1 and CE2. In other words, the filling connection portion FI3 may be disposed at the same level as a boundary of the first and second holes HO1 and HO2.

Ideally, the upper and lower portions of the first and second holes HO1 and HO2 are required to have the same width, but the upper and lower portions of the same hole may have different widths. For example, the width of the lower portion of each of the first and second holes HO1 and HO2 may be smaller than the width of the upper portion. As described above, when the widths of the upper and lower portions of each of the first and second holes HO1 and HO2 are different from each other, a minimum width of the upper portion FI2 of the filling film FI in the second direction D2 may be defined as a first width W1, and a maximum width of the filling connection portion FI3 in the second direction D2 may be defined as a second width W2. The second width W2 may be smaller than the first width W1.

The filling film FI may have an integrated structure. In other words, the lower portion FI1, the upper portion FI2, and the filling connection portion FI3 of the filling film FI may be simultaneously formed in one deposition process. Therefore, the lower portion FI1, the upper portion FI2, and the filling connection portion FI3 of the filling film FI may be integrally connected to each other without a boundary. The filling film FI may pass through the first stack CE1 and the second stack CE2. In other words, the filling film FI may pass through the first and second holes HO1 and HO2. A length of the filling film FI in the third direction D3 may be the same as a sum of a length of the first and second stacks CE1 and CE2 in the third direction D3. For example, the filling film FI may include silicon oxide.

The channel film CL covering an outer sidewall of the filling film FI may be provided. In other words, the filling film FI may be provided in the channel film CL. The channel film CL may include a first channel sidewall portion CL1 covering an outer sidewall of the lower portion FI1 of the filling film FI, a second channel sidewall portion CL2 covering an outer sidewall of the upper portion FI2 of the filling film FI, and a channel interposition portion CL3 connecting the first channel sidewall portion CL1 and the second channel sidewall portion CL2 to each other. The first channel sidewall portion CL1 may be formed along the inner sidewall of the first memory film ML1. The second channel sidewall portion CL2 may be formed along the inner sidewall of the second memory film ML2. The channel interposition portion CL3 may cover an outer sidewall of the filling connection portion FI3 of the filling film FI.

The channel interposition portion CL3 may include a first channel connection portion CL3_R1, a second channel connection portion CL3_R2, and a third channel connection portion CL3_R3. The first channel connection portion CL3_R1 may be connected to the first channel sidewall portion CL1, the second channel connection portion CL3_R2 may be connected to the second channel sidewall portion CL2, and the third channel connection portion CL3_R3 may connect the first and second channel connection portions CL3_R1 and CL3_R2 to each other. Each of the first to third channel connection portions CL3_R1, CL3_R2, and CL3_R3 may have a ring shape.

A width in the second direction D2 between an outer sidewall and an inner sidewall of the first channel connection portion CL3_R1 may be defined as a third width W3. A width in the second direction D2 between an outer sidewall and an inner sidewall of the second channel connection portion CL3_R2 may be defined as a fourth width W4. A width in the second direction D2 between an outer sidewall and an inner sidewall of the third channel connection portion CL3_R3 may be defined as a fifth width W5.

The third width W3 may be greater than the fourth width W4. The fourth width W4 may be greater than the fifth width W5. The fifth width W5 may be substantially the same as a width of the first channel sidewall portion CL1. The width of the first channel sidewall portion CL1 may be the same with the width of the second channel sidewall portion CL2. For avoidance of confusion the width of an element in the present disclosure is measured in the second direction D2. Both the third width W3 and the fourth width W4 may each be greater than the width of the first channel sidewall portion CL1 (or the second channel sidewall portion CL2).

A lower surface of the first channel connection portion CL3_R1 may be in direct contact with an upper surface of the lower portion FI1 of the filling film FI. The inner sidewall of the first channel connection portion CL3_R1 may be in direct contact with the outer sidewall of the filling connection portion FI3 of the filling film FI. An upper surface of the first channel connection portion CL3_R1 may be positioned at the same level as the boundary between the first and second stacks CE1 and CE2. In other words, the upper surface of the first channel connection portion CL3_R1 may be positioned at the same level as the boundary between the first and second holes HO1 and HO2.

An upper surface of the second channel connection portion CL3_R2 may be in direct contact with a lower surface of the upper portion FI2 of the filling film FI. The inner sidewall of the second channel connection portion CL3_R2 may be in direct contact with the outer sidewall of the filling connection portion FI3 of the filling film FI.

The channel film CL may have an integrated structure. In other words, the first channel sidewall portion CL1, the second channel sidewall portion CL2, and the channel interposition portion CL3 of the channel film CL may be integrally connected to each other without a boundary. The channel film CL may pass through the first stack CE1 and the second stack CE2. In other words, the channel film CL may pass through the first and second holes HO1 and HO2. A length of the channel film CL in the third direction D3 may be the same as the sum of the length of the first and second stacks CE1 and CE2 in the third direction D3. The channel film CL may be formed of a semiconductor film. For example, the channel film CL may be formed of a doped polysilicon film or an undoped polysilicon film.

The first memory film ML1 and the second memory film ML2 covering an outer sidewall of the channel film CL may be provided. The first memory film ML1 may be provided in the first stack CE1. The first memory film ML1 may pass through the first stack CE1. The second memory film ML2 may be provided in the second stack CE2. The second memory film ML2 may pass through the second stack CE2.

The first memory film ML1 may include a first tunnel film TI1 surrounding an outer sidewall of the first channel sidewall portion CL1 of the channel film CL, a first storage film DS1 surrounding an outer sidewall of the first tunnel film TI1, and a first blocking film BI1 surrounding an outer sidewall of the first storage film DS1.

The second memory film ML2 may include a second tunnel film TI2 surrounding an outer sidewall of the second channel sidewall portion CL2 of the channel film CL, a second storage film DS2 surrounding an outer sidewall of the second tunnel film TI2, and a second blocking film BI2 surrounding an outer sidewall of the second storage film DS2.

The first and second tunnel films TI1 and TI2 may be spaced apart from each other. The first and second tunnel films TI1 and TI2 may include an oxide capable of charge tunneling. For example, the first and second tunnel films TI1 and TI2 may include silicon oxide.

The first and second storage films DS1 and DS2 may be spaced apart from each other. The first and second storage films DS1 and DS2 may include a material in which charge may be trapped. For example, the first and second storage films DS1 and DS2 may include at least one of nitride, silicon, a phase change material, and nanodot.

The first and second blocking films BI1 and BI2 may be spaced apart from each other. The first and second blocking films BI1 and BI2 may include an oxide capable of blocking movement of a charge. For example, the first and second blocking films BI1 and BI2 may include silicon oxide.

The second tunnel film TI2 may include a tunnel sidewall portion TI2_S and a tunnel pattern portion TI2_R. A lowermost portion of the second tunnel film TI2 may be defined as the tunnel pattern portion TI2_R. The tunnel pattern portion TI2_R may have a ring shape. The tunnel pattern portion TI2_R may be a horizontal layer extending in the first and second directions D1 and D2. An upper surface of the tunnel pattern portion TI2_R may be in direct contact with a lower surface of the second channel connection portion CL3_R2 of the channel interposition portion CL3 of the channel film CL. An inner sidewall of the tunnel pattern portion TI2_R may be in direct contact with an outer sidewall of the third channel connection portion CL3_R3 of the channel interposition portion CL3 of the channel film CL. A width in the second direction D2 between an outer sidewall and an inner sidewall of the tunnel pattern portion TI2_R may be defined as a sixth width W6. The sixth width W6 may be greater than a width of the first tunnel film TI1. The sixth width W6 may be greater than a width of the tunnel sidewall portion TI2_S of the second tunnel film TI2.

The second storage film DS2 may include a storage sidewall portion DS2_S and a storage pattern portion DS2_R. A lowermost portion of the second storage film DS2 may be defined as the storage pattern portion DS2_R. The storage pattern portion DS2_R may have a ring shape. The storage pattern portion DS2_R may be a horizontal layer extending in the first and second directions D1 and D2. An upper surface of the storage pattern portion DS2_R may be in direct contact with a lower surface of the tunnel pattern portion TI2_R of the second tunnel film TI2. An inner sidewall of the storage pattern portion DS2_R may be in direct contact with the outer sidewall of the third channel connection portion CL3_R3 of the channel interposition portion CL3 of the channel film CL. A width in the second direction D2 between an outer sidewall and the inner sidewall of the storage pattern portion DS2_R may be defined as a seventh width W7. The seventh width W7 may be greater than a width of the first storage film DS1. The seventh width W7 may be greater than a width of the storage sidewall portion DS2_S of the second storage film DS2. The seventh width W7 may be greater than the sixth width W6.

The second blocking film BI2 may include a blocking sidewall portion BI2_S and a blocking pattern portion BI2_R. A lowermost portion of the second blocking film BI2 may be defined as the blocking pattern portion BI2_R. The blocking pattern portion BI2_R may have a ring shape. The blocking pattern portion BI2_R may be a horizontal layer extending in the first and second directions D1 and D2. An upper surface of the blocking pattern portion BI2_R may be in direct contact with a lower surface of the storage pattern portion DS2_R of the second storage film DS2. An inner sidewall of the blocking pattern portion BI2_R may be in direct contact with the outer sidewall of the third channel connection portion CL3_R3 of the channel interposition portion CL3 of the channel film CL. A lower surface of the blocking pattern portion BI2_R may be in direct contact with the upper surface of the first channel connection portion CL3_R1 of the channel interposition portion CL3 of the channel film CL. A width in the second direction D2 between an outer sidewall and the inner sidewall of the blocking pattern portion BI2_R may be defined as an eighth width W8. The eighth width W8 may be greater than a width of the first blocking film BI1. The eighth width W8 may be greater than a width of the blocking sidewall portion BI2_S of the second blocking film BI2. The eighth width W8 may be greater than the seventh width W7.

A length of the first memory film ML1 in the third direction D3 may be substantially the same as a length of the first stack CE1 in the third direction D3. A length of the second memory film ML2 in the third direction D3 may be substantially the same as a length of the second stack CE2 in the third direction D3. A sum of the length of the first memory film ML1 in the third direction D3 and the length of the second memory film ML2 in the third direction D3 may be substantially the same as the sum of the length of the channel film CL in the third direction D3 and the length of the filling film FI in the third direction D3.

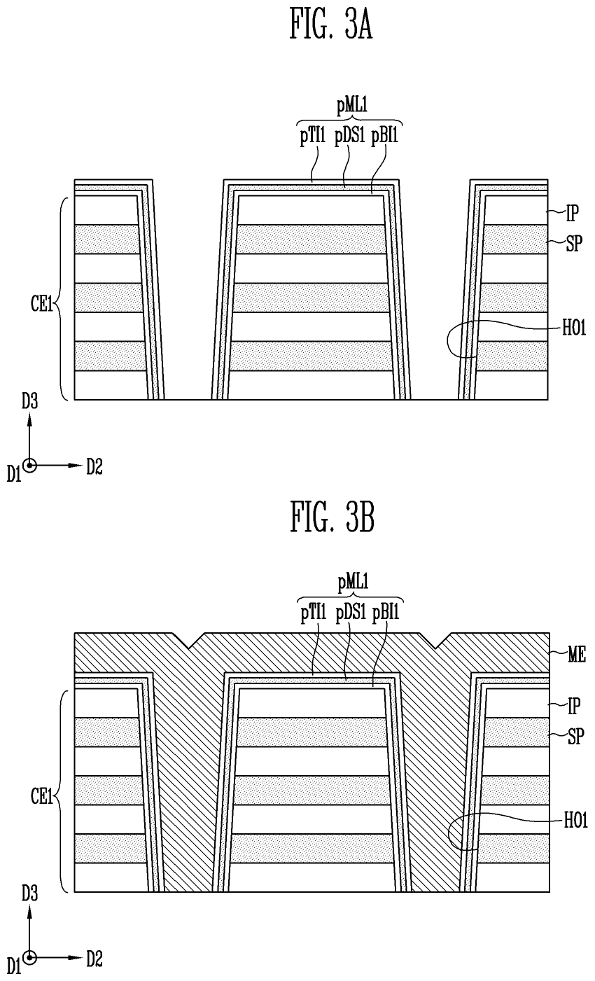

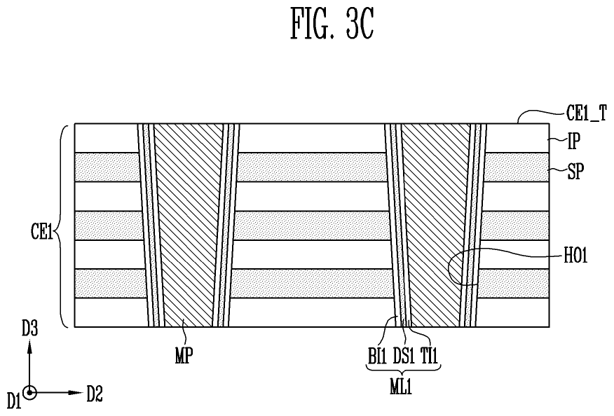

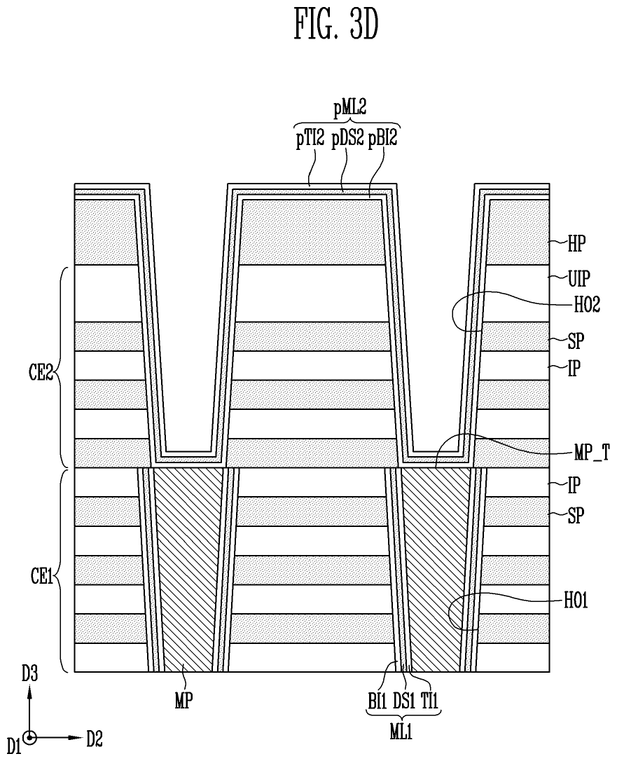

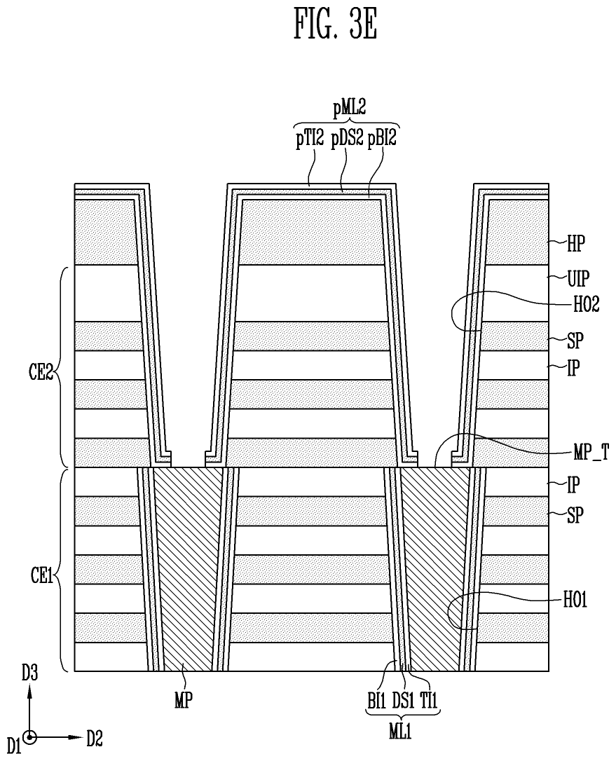

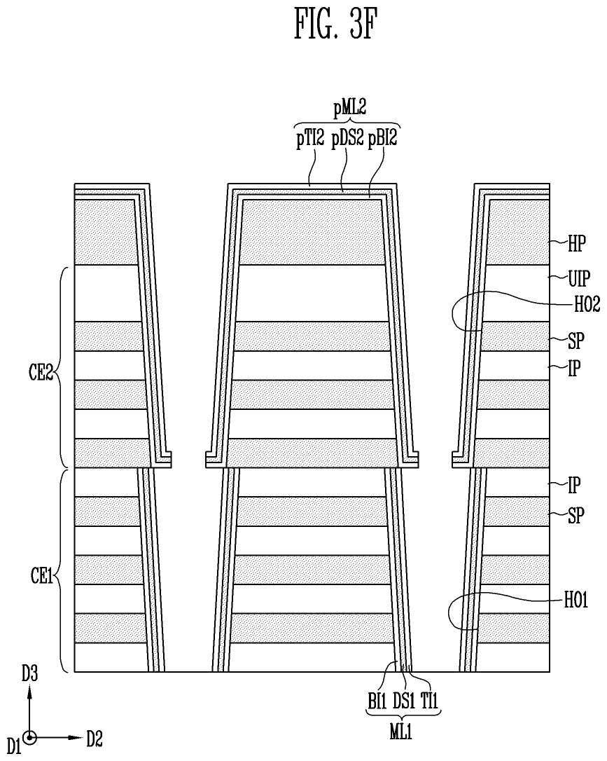

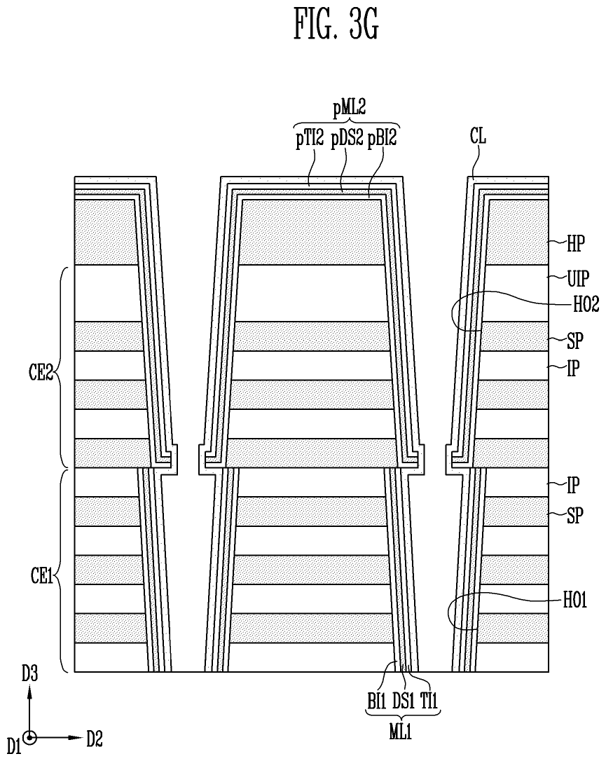

FIGS. 3A to 3G are cross-sectional views describing a method of manufacturing the semiconductor memory device according to FIGS. 2A and 2B.

Referring to FIG. 3A, the first stack CE1 may be formed on a substrate. The first stack CE1 may include insulating films and gate sacrificial films alternately stacked. Each of the insulating films and the gate sacrificial films may be alternately stacked through a deposition process. For example, the insulating films may include silicon oxide. For example, the gate sacrificial films may include silicon nitride.

The first holes HO1 passing through the first stack CE1 may be formed. Forming the first holes HO1 may include forming a mask pattern (not shown) on the first stack CE1, patterning the first stack CE1 using the mask pattern as an etching mask, and removing the mask pattern. As the first holes HO1 are formed, the insulating films and the gate sacrificial films may be patterned, for example, by etching to form the insulating patterns IP and gate sacrificial patterns SP of the first stack CE1.

A first preliminary memory film pML1 may be formed along a surface of the first stack CE1. The first preliminary memory film pML1 may include a first preliminary blocking film pBI1, a first preliminary storage film pDS1, and a first preliminary tunnel film pTI1. Forming the first preliminary memory film pML1 may include conformally forming the first preliminary blocking film pBI1 along the surface of the first stack CE1, conformally forming the first preliminary storage film pDS1 on the first preliminary blocking film pBI1, and conformally forming the first preliminary tunnel film pTI1 on the first preliminary storage film pDS1. The first preliminary memory film pML1 may partially fill the first holes HO1. In other words, the first preliminary memory film pML1 may not completely fill the first holes HO1.

Referring to FIG. 3B, a channel sacrificial film ME may be formed in the first holes HO1 in which the first preliminary memory film pML1 is formed. The first holes HO1 may be completely filled by the channel sacrificial film ME. The channel sacrificial film ME may have an etching selectivity with respect to the first preliminary memory film pML1. The channel sacrificial film ME may include a metal material of which an etching speed is higher than that of the first preliminary memory film pML1. For example, the channel sacrificial film ME may be formed of a material having an etching selectivity with respect to the first preliminary tunnel film pTI1. For example, the channel sacrificial film ME may be formed of a metal material of which an etching speed is higher than that of the first preliminary tunnel film pTI1.

Referring to FIG. 3C, a planarization process may be performed to expose an upper surface CE1_T of the first stack CE1. The planarization process may be a chemical mechanical polishing (CMP) process. By the planarization process, a portion of the first preliminary memory film pML1 and a portion of the channel sacrificial film ME positioned at a level higher than the upper surface CE1_T of the first stack CE1 may be removed, and the upper surface CE1_T of the first stack CE1 may be exposed. In other words, the planarization process removes all portions of the first preliminary memory film pML1 above the first stack CE1.

By the planarization process, a portion of the first preliminary memory film pML1 may be removed, and the first preliminary memory film pML1 remaining in the first hole HO1 may be defined as the first memory film ML1. In other words, the first memory film ML1 may be formed. The first memory film ML1 may include the first tunnel film TI1, the first storage film DS1, and the first blocking film BI1.

By the planarization process, a portion of the channel sacrificial film ME may be removed to form channel sacrificial patterns MP.

Referring to FIG. 3D, the second stack CE2 may then be formed on the first stack CE1. Forming the second stack CE2 may include alternately stacking insulating films and gate sacrificial films on the first stack CE1, and forming an upper insulating film UIP. For example, the upper insulating film UIP may include silicon oxide.

A hard mask film may be formed on the upper insulating film. For example, the hard mask film HP may include silicon nitride.

The second holes HO2 passing through the second stack CE2 and the hard mask film may be formed. Forming the second holes HO2 may include forming a mask pattern including openings exposing a portion of the hard mask film on the hard mask film, patterning the hard mask film and the second stack CE2 using the mask pattern as an etching mask, and removing the mask pattern. As the second holes HO2 are formed, the hard mask film may be patterned, for example, by etching to form a hard mask pattern HP, the upper insulating film may be patterned, for example, by etching to form an upper insulating pattern UIP, and the insulating films and the gate sacrificial films may be patterned, for example, by etching to form the insulating patterns IP and the gate sacrificial patterns SP. Upper surfaces MP_T of the channel sacrificial patterns MP in the first stack CE1 may be exposed by the second holes HO2.

A second preliminary memory film pML2 may be formed along a surface of the second stack CE2 and the hard mask pattern HP. The second preliminary memory film pML2 may include a second preliminary blocking film pBI2, a second preliminary storage film pDS2, and a second preliminary tunnel film pTI2. Forming the second preliminary memory film pML2 may include conformally forming the second preliminary blocking film pBI2 along the surface of the second stack CE2 and the hard mask pattern HP, conformally forming the second preliminary storage film pDS2 on the second preliminary blocking film pBI2, and conformally forming the second preliminary tunnel film pTI2 on the second preliminary storage film pDS2. The second preliminary memory film pML2 may partially fill the second holes HO2. In other words, the second preliminary memory film pML2 may not completely fill the second holes HO2. The second preliminary memory film pML2 may cover the upper surfaces MP_T of the channel sacrificial patterns MP.

Referring to FIG. 3E, a portion of the second preliminary memory film pML2 positioned on the upper surfaces MP_T of the channel sacrificial patterns MP of the first stack CE1 may be patterned, for example, by etching. As the second preliminary memory film pML2 is patterned, a portion of the upper surface MP_T of the channel sacrificial pattern MP may be exposed again. As the second preliminary memory film pML2 is patterned, blocking pattern portions BI2_R (refer to FIG. 2B) may be formed in the second preliminary blocking film pBI2, storage pattern portions DS2_R (refer to FIG. 2B) may be formed in the second preliminary storage film pDS2, and tunnel pattern portions TI2_R (refer to FIG. 2B) may be formed in the second preliminary tunnel film pTI2.

Referring to FIG. 3F, the channel sacrificial patterns MP of the first stack CE1 may be selectively removed. Selectively removing the channel sacrificial patterns MP may be performed by a wet etching method using an etchant capable of selectively removing the channel sacrificial patterns MP. As the channel sacrificial patterns MP are removed, the inner sidewalls of the first memory films ML1 may be exposed. As the channel sacrificial patterns MP are removed, a central portion of the first holes HO1 may be exposed again.

Referring to FIG. 3G, the channel film CL covering the first memory films ML1 and the second preliminary memory films pML2 may be formed. The channel film CL may be formed on the inner sidewall of the first memory film ML1 and an inner sidewall of the second preliminary memory film pML2. The channel film CL may include the first channel sidewall portion CL1 (refer to FIG. 2B) in the first stack CE1, the second channel sidewall portion CL2 (refer to FIG. 2B) in the second stack CE2, and the channel interposition portion CL3 (refer to FIG. 2B) connecting the first and second channel sidewall portions CL1 and CL2 to each other.

The channel film CL may be formed in one step as a single, continuous element without any interfaces therein. In other words, the channel film CL may be simultaneously formed in the first and second holes HO1 and HO2. The channel film CL being formed as a single, continuous element may pass through the first and second stacks CE1 and CE2.

When the channel film CL is formed, then the filling film FI completely filling the first and second holes HO1 and HO2 may be formed (refer to FIG. 2A). The filling film FI may be formed in a single step as a single, continuous element without any interfaces therein. The filling film FI being formed as a single, continuous element may pass through the first and second stacks CE1 and CE2.

When the filling film FI is formed, the planarization process may be performed to remove the hard mask pattern HP. An upper portion of the second preliminary memory film pML2, an upper portion of the channel film CL, and an upper portion of the filling film FI may be removed together with the hard mask pattern HP. As the upper portion of the second preliminary memory film pML2 is removed, the second memory films ML2 may be formed. By the planarization process, the channel structures CST including the first memory film ML1, the second memory film ML2, the channel film CL, and the filling film FI may be formed (refer to FIG. 2A).

When the channel structures CST are formed, the gate sacrificial patterns SP may be selectively removed. As the gate sacrificial patterns SP are selectively removed, empty spaces may be formed between the insulating patterns IP and the upper insulating pattern UIP. The conductive patterns CP filling the empty spaces may be formed (refer to FIG. 2A).

In the semiconductor memory device according to the present embodiment, after forming the first memory films ML1 in the first holes HO1 of the first stack CE1, the second memory films ML2 are formed in the second holes HO2 of the second stack CE2 using the same processes, thus ensuring that the widths and electrical characteristics of the first and second memory films ML1 and ML2 are uniform. In addition, the channel layer CL covering both the first and second memory films ML1 and ML2 is formed in a single step to ensure that the channel layer CL is a single part. Likewise, the filling film FI is formed as an integral part in a single step. In other words, the widths and electrical characteristics of the upper and lower portions of the channel structure CST may be uniform.

In the semiconductor memory device according to the present embodiment, the channel film CL is simultaneously formed in the first hole HO1 of the first stack CE1 and the second hole HO2 of the second stack CE2. Therefore, the channel film CL may be formed by one process, and time and cost may be reduced.

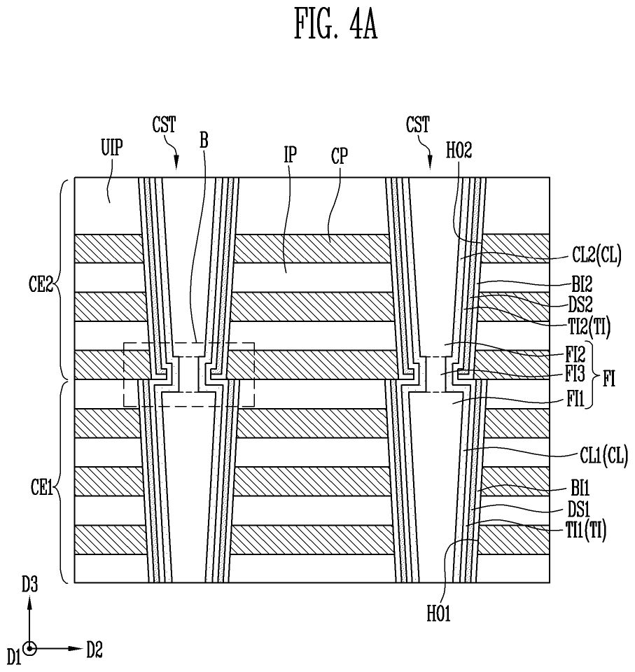

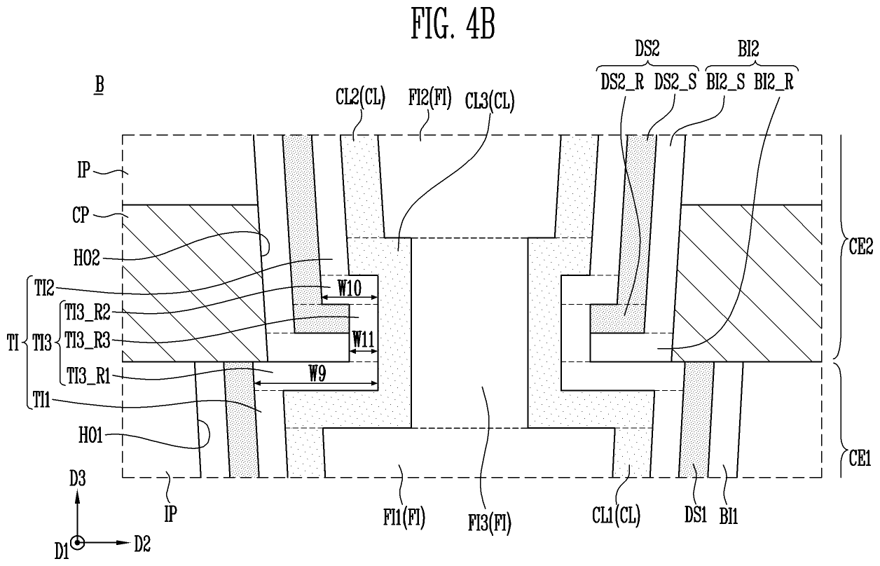

FIG. 4A is a cross-sectional view of a semiconductor memory device according to an embodiment of the present disclosure. FIG. 4B is an enlarged view of a B region of FIG. 4A.

The semiconductor memory device according to the present embodiment is similar to the semiconductor memory device according to FIGS. 2A and 2B except as described below.

Referring to FIGS. 4A and 4B, the channel structure CST of the semiconductor memory device according to the present embodiment may include the first blocking film BI1 and the first storage film DS1 sequentially formed along the inner sidewall of the first hole HO1, the second blocking film BI2 and the second storage film DS2 sequentially formed along the inner sidewall of the second hole HO2, the tunnel film TI formed along an inner sidewall of the first storage film DS1 and an inner sidewall of the second storage film DS2, the channel film CL in the tunnel film TI, and the filling film FI in the channel film CL.

The channel film CL may include the first channel sidewall portion CL1, the second channel sidewall portion CL2, and the channel interposition portion CL3, and the channel interposition portion CL3 may include the first to third channel connection portions CL3_R1, CL3_R2, and CL3_R3 (refer to FIG. 2B). The filling film FI may include the lower portion FI1, the upper portion FI2, and the filling connection portion FI3. The second blocking film BI2 may include the blocking sidewall portion BI2_S and the blocking pattern portion BI2_R. The second storage film DS2 may include the storage sidewall portion DS2_S and the storage pattern portion DS2_R. The first and second blocking films BI1 and BI2 may be spaced apart from each other. The first and second storage films DS1 and DS2 may be spaced apart from each other.

The tunnel film TI may include a first tunnel sidewall portion TI1 formed along the inner sidewall of the first storage film DS1, a second tunnel sidewall portion TI2 formed along the inner sidewall of the second storage film DS2, and a tunnel interposition portion TI3 connecting the first and second tunnel sidewall portions TI1 and TI2.

The tunnel interposition portion TI3 may include a first tunnel connection portion TI3_R1 connected to the first tunnel sidewall portion TI1, a second tunnel connection portion TI3_R2 connected to the second tunnel sidewall portion TI2, and a third tunnel connection portion TI3_R3 connecting the first and second tunnel connection portions TI3_R1 and TI3_R2 to each other.

A width in the second direction D2 between an outer sidewall and an inner sidewall of the first tunnel connection portion TI3_R1 may be defined as a ninth width W9. A width in the second direction D2 between an outer sidewall and an inner sidewall of the second tunnel connection portion TI3_R2 may be defined as a tenth width W10. A width in the second direction D2 between an outer sidewall and an inner sidewall of the third tunnel connection portion TI3_R3 may be defined as an eleventh width W11.

The tenth width W10 may be smaller than the ninth width W9. The eleventh width W11 may be smaller than the tenth width W10. The eleventh width W11 may be substantially the same as a width of the first and second tunnel sidewall portions TI1 and TI2. The ninth width W9 and the tenth width W10 may be greater than the width of the first and second tunnel sidewall portions TI1 and TI2.

An upper surface of the first tunnel connection portion TI3_R1 may be in direct contact with the lower surface of the blocking pattern portion BI2_R of the second blocking film BI2. A lower surface of the second tunnel connection portion TI3_R2 may be in direct contact with the upper surface of the storage pattern portion DS2_R of the second storage film DS2. The outer sidewall of the third tunnel connection portion TI3_R3 may be in direct contact with the inner sidewall of the storage pattern portion DS2_R of the second storage film DS2 and the inner sidewall of the blocking pattern portion BI2_R of the second blocking film BI2.

In the semiconductor memory device according to the present embodiment, the tunnel film TI, the channel film CL, and the filling film FI may each be a single continuous element without any interfaces therein. Each of the tunnel film TI, the channel film CL, and the filling film FI may pass through the first and second stacks CE1 and CE2. In other words, each of the tunnel film TI, the channel film CL, and the filling film FI may be formed along the inner sidewall of the first hole HO1 and the inner sidewall of the second hole HO2.

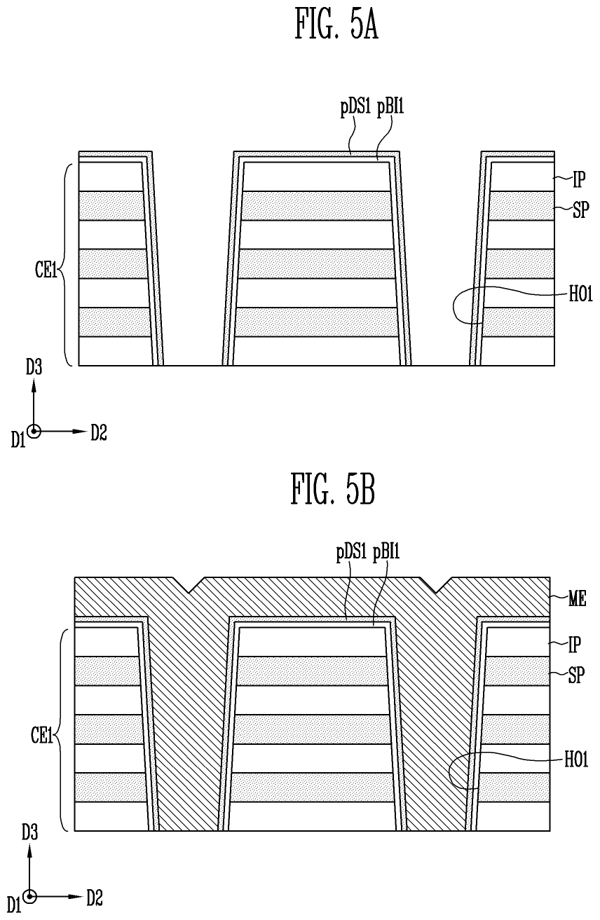

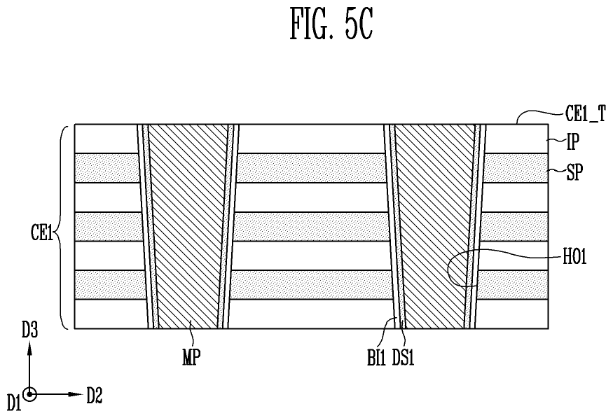

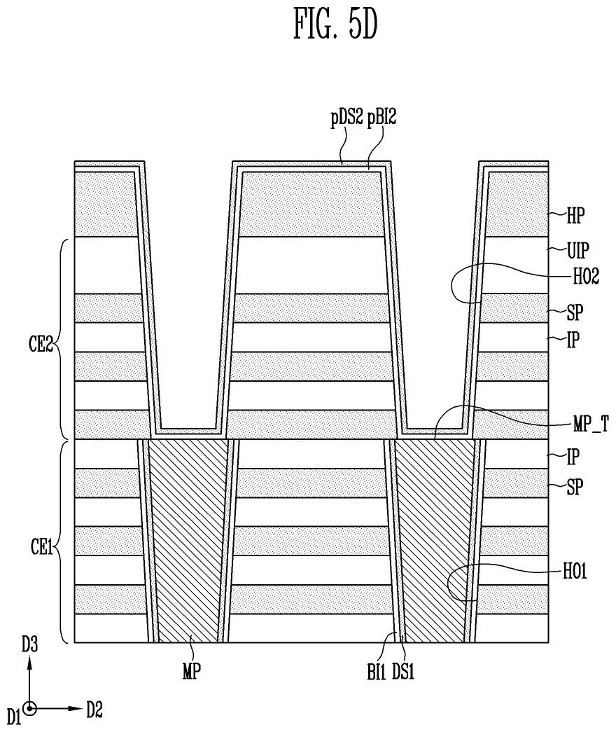

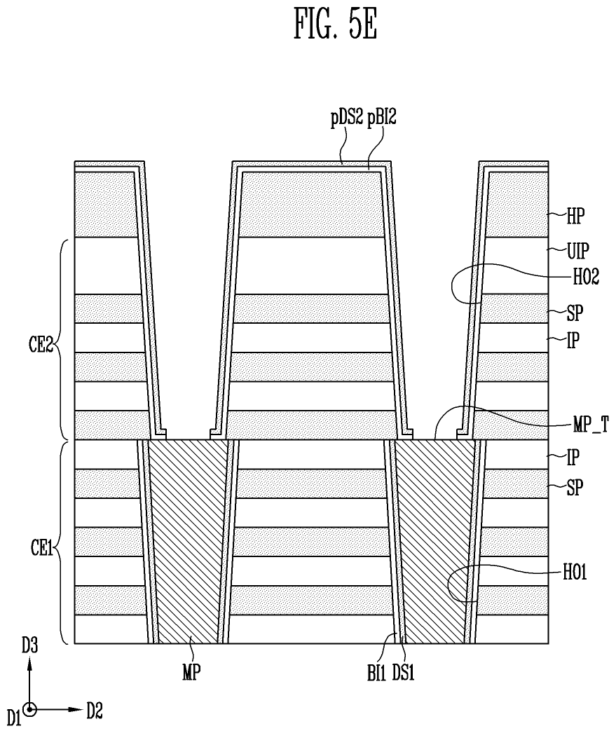

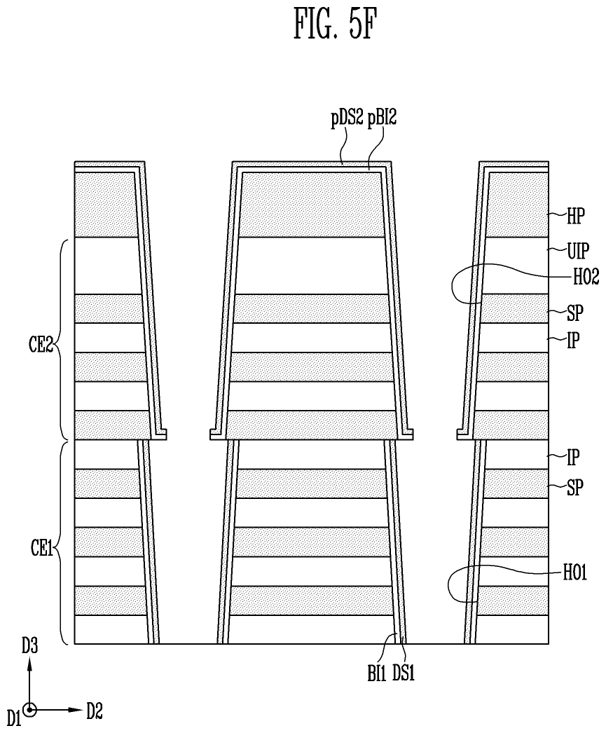

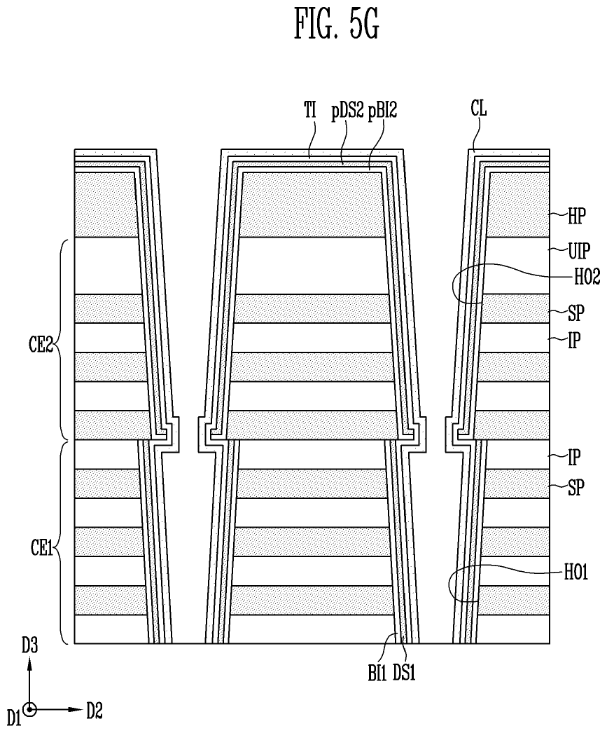

FIGS. 5A to 5G are cross-sectional views illustrating a method of manufacturing the semiconductor memory device according to FIGS. 4A and 4B.

The method of manufacturing the semiconductor memory device according to the present embodiment is similar to the method of manufacturing the semiconductor memory device described with reference to FIGS. 3A to 3G except as described below.

Referring to FIG. 5A, the first stack CE1 may be formed on the substrate, and the first holes HO1 passing through the first stack CE1 may be formed.

The first preliminary blocking film pBI1 and the first preliminary storage film pDS1 may be formed on the first stack CE1. Forming the first preliminary blocking film pBI1 and the first preliminary storage film pDS1 may include conformally forming the first preliminary blocking film pBI1 along the surface of the first stack CE1, and conformally forming the first preliminary storage film pDS1 on the first preliminary blocking film pBI1.

Referring to FIG. 5B, the channel sacrificial film ME may be formed in the first hole HO1 in which the first preliminary blocking film pBI1 and the first preliminary storage film pDS1 are formed. The first holes HO1 may be completely filled with the channel sacrificial film ME.

Referring to FIG. 5C, a planarization process may be performed to expose the upper surface CE1_T of the first stack CE1. By the planarization process, a portion of the first preliminary blocking film pBI1 positioned at a level higher than the upper surface CE1_T of the first stack CE1, a portion of the first preliminary storage film pDS1, and a portion of the channel sacrificial film ME may be removed, and the upper surface CE1_T of the first stack CE1 may be exposed.

By the planarization process, a portion of the first preliminary blocking film pBI1 may be removed, and the first preliminary blocking film pBI1 remaining in the first hole HO1 may be defined as the first blocking film BI1. In other words, the first blocking film BI1 may be formed. By the planarization process, a portion of the first preliminary storage film pDS1 may be removed, and the first preliminary storage film pDS1 remaining in the first hole HO1 may be defined as the first storage film DS1. In other words, the first storage film DS1 may be formed.

By the planarization process, a portion of the channel sacrificial film ME may be removed to form the channel sacrificial patterns MP.

Referring to FIG. 5D, the second stack CE2 and the hard mask pattern HP on which the second holes HO2 are formed may be formed on the first stack CE1. For example, after forming the second stack CE2 on the first stack CE1, the hard mask pattern HP in which openings exposing a portion of the upper surface of the second stack CE2 are formed may be formed on the second stack CE2. Subsequently, the second stack CE2 exposed through the openings of the hard mask pattern HP may be etched to form the second holes HO2. The etching process for forming the second holes HO2 may be performed until the channel sacrificial patterns MP in the first stack CE1 are exposed.

When the second holes HO2 are formed, the second preliminary blocking film pBI2 and the second preliminary storage film pDS2 may be sequentially formed along the surface of the second stack CE2 and the hard mask pattern HP.

Referring to FIG. 5E, a portion of the second preliminary blocking film pBI2 and a portion of the second preliminary storage film pDS2 positioned on the upper surfaces MP_T of the channel sacrificial patterns MP may be patterned, for example, by etching. Therefore, the upper surfaces MP_T of the channel sacrificial patterns MP may be exposed again.

Referring to FIG. 5F, the channel sacrificial patterns MP may be selectively removed (e.g., by etching) to open a portion of the first holes HO1 again.

Referring to FIG. 5G, the tunnel film TI covering the first storage films DS1 and the second preliminary storage film pDS2 may be formed. The tunnel film TI may be conformally formed on the first storage films DS1 and the second preliminary storage films pDS2.

The tunnel film TI may be formed by one process in a single, continuous element without any interfaces therein. The tunnel film TI being formed as a single, continuous element may pass through the first and second stacks CE1 and CE2.

The channel film CL may be formed along the surface of the tunnel film TI. The channel film CL may be conformally formed on the tunnel film TI. The channel film CL may be formed by one process in a single, continuous element without any interfaces therein. The channel film CL being formed as a single, continuous element may pass through the first and second stacks CE1 and CE2.

When the channel film CL is formed, the filling film FI completely filling the first and second holes HO1 and HO2 may be formed (refer to FIG. 4A). The filling film FI may be formed by one process in a single, continuous element without any interfaces therein. The filling film FI being formed as a single, continuous element may pass through the first and second stacks CE1 and CE2.

When the filling film FI is formed, a planarization process may be performed to form the channel structures CST (refer to FIG. 4A). Each of the channel structures CST may include the first and second blocking films BI1 and BI2, the first and second storage films DS1 and DS2, the tunnel film TI, the channel film CL, and the filling film FI.

When the channel structures CST are formed, the gate sacrificial patterns SP may be removed and the conductive patterns CP may be formed (refer to FIG. 4A).

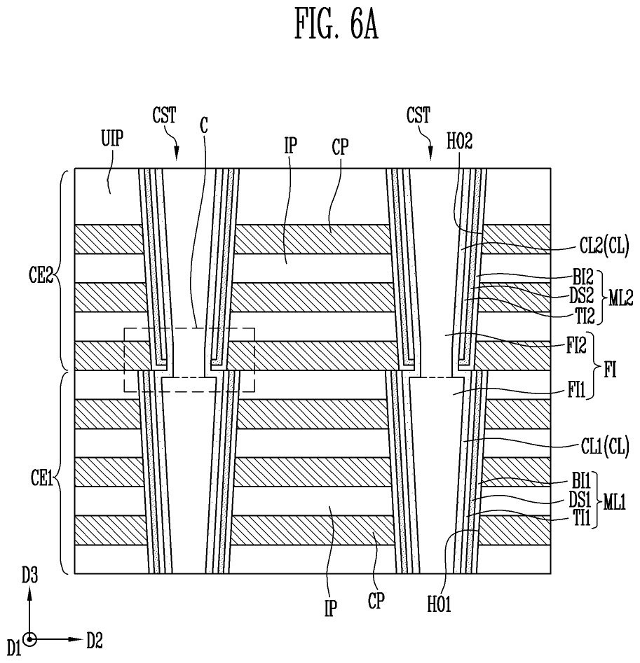

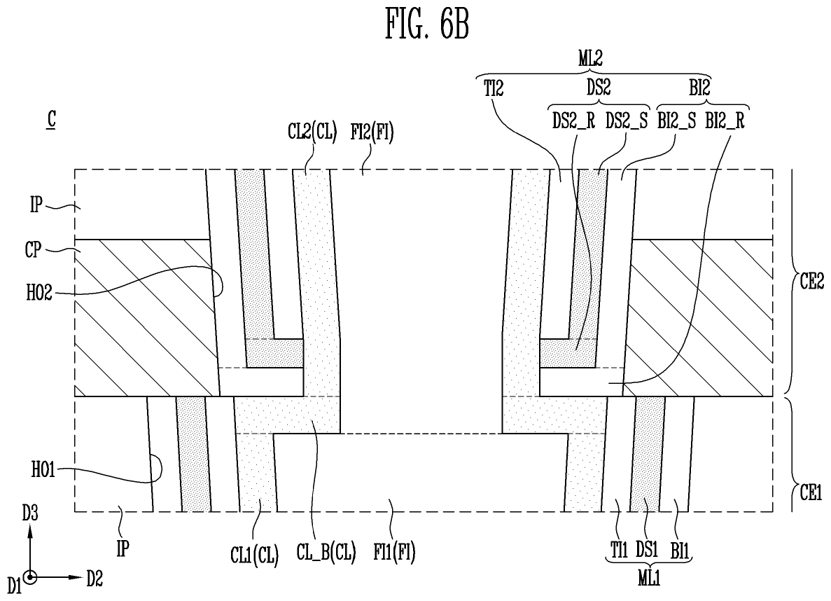

FIG. 6A is a cross-sectional view of a semiconductor memory device according to an embodiment of the present disclosure. FIG. 6B is an enlarged view of a C region of FIG. 6A.

The semiconductor memory device according to the present embodiment may be similar to the semiconductor memory device according to FIGS. 2A and 2B except as described below. Referring to FIGS. 6A and 6B, a width of the second tunnel film TI2 of the memory device according to the present embodiment may be constant in the second direction D2. In other words, the second tunnel film TI2 of the memory device according to the present embodiment may not include the tunnel pattern portion TI2_R of the second tunnel film TI2 of the memory device according to FIGS. 2A and 2B.

The channel film CL may include the first channel sidewall portion CL1 formed along the inner sidewall of the first memory film ML1, the second channel sidewall portion CL2 formed along the inner sidewall of the second memory film ML2, and a channel boundary portion CL_B connecting the first and second channel sidewall portions CL1 and CL2 to each other.

An outer sidewall of the second channel sidewall portion CL2 may be in direct contact with the inner sidewall of the storage pattern portion DS2_R of the second storage film DS2, the inner sidewall of the blocking pattern portion BI2_R of the second blocking film BI2 and the inner sidewall of the second tunnel film TI2.

The channel boundary portion CL_B may have a ring shape. An upper surface of the channel boundary portion CL_B may be positioned at the same level as the boundary of the first and second stacks CE1 and CE2. The upper surface of the channel boundary portion CL_B may be in direct contact with the lower surface of the blocking pattern portion BI2_R of the second blocking film BI2. An outer sidewall of the channel boundary portion CL_B may be in direct contact with an inner sidewall of the first tunnel film TI1.

The filling film FI may include the lower portion FI1 passing through the first stack CE1 and the upper portion FI2 passing through the second stack CE2. The lower portion FI1 and the upper portion FI2 may be directly connected to each other. A boundary between the lower portion FI1 and the upper portion FI2 of the filling film FI may be positioned at the same level as a lower surface of the channel boundary portion CL_B.

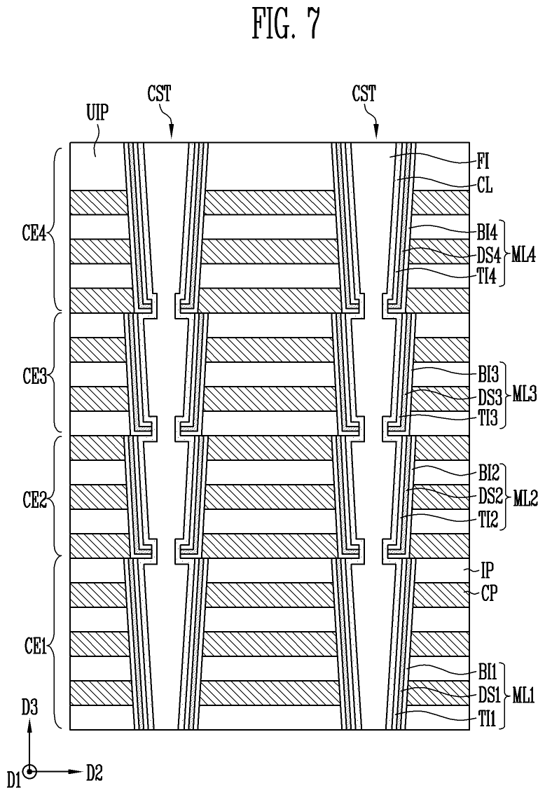

FIG. 7 is a cross-sectional view of a semiconductor memory device according to an embodiment of the present disclosure.

The semiconductor memory device according to the present embodiment is similar to the semiconductor memory device described with reference to FIGS. 2A and 2B except as described below.

Referring to FIG. 7, the semiconductor memory device according to the present embodiment may include first to fourth stacks CE1, CE2, CE3, and CE4 sequentially stacked along the third direction D3. The fourth stack CE4 may include an upper insulating pattern UIP.

The channel structure CST may include a first memory film ML1 in the first stack CE1, a second memory film ML2 in the second stack CE2, a third memory film ML3 in the third stack CE3, and a fourth memory film ML4 in the fourth stack CE4. The first to fourth memory films ML1, ML2, ML3, and ML4 may be separated from each other and may be formed in the first to fourth stacks CE1, CE2, CE3, and CE4, respectively.

The first memory film ML1 may include a first blocking film BI1, a first storage film DS1, and a first tunnel film TI1, the second memory film ML2 may include a second blocking film BI2, a second storage film DS2, and a second tunnel film TI2, the third memory film ML3 may include a third blocking film BI3, a third storage film DS3, and a third tunnel film TI3, and the fourth memory film ML4 may include a fourth blocking film BI4, a fourth storage film DS4, and a fourth tunnel film TI4.

Each of the first to fourth blocking films BI1, BI2, BI3, and BI4 may include a blocking pattern portion, each of the first to fourth storage films DS1, DS2, DS3, and DS4 may include a storage pattern portion, and the first to fourth tunnel films TI1, TI2, TI3, and TI4 may include a tunnel pattern portion.

The channel structure CST may include a single, continuous channel film CL passing through the first to fourth stacks CE1, CE2, CE3, and CE4. The channel film CL may include channel interposition portions connecting the channel sidewall portions to each other. Each of the channel interposition portions may include portions having a width greater than a width of the channel sidewall portions.

The channel structure CST may include a filling film FI of an integrated structure passing through the first to fourth stacks CE1, CE2, CE3, and CE4.

A method of manufacturing the semiconductor memory device according to the present embodiment will be described. The first stack CE1, first holes HO1, and the first memory films ML1 may be formed, the second stack CE2, second holes HO2, and the second memory films ML2 may be formed, the third stack CE3, third holes HO3, and the third memory films ML3 may be formed, and the fourth stack CE4, fourth holes HO4, the fourth memory films ML4 may be formed, and then the channel film CL and the filling film FI may be formed. Therefore, the channel film CL and the filling film FI may each be formed as single, continuous elements passing through the first to fourth stacks CE1, CE2, CE3, and CE4.

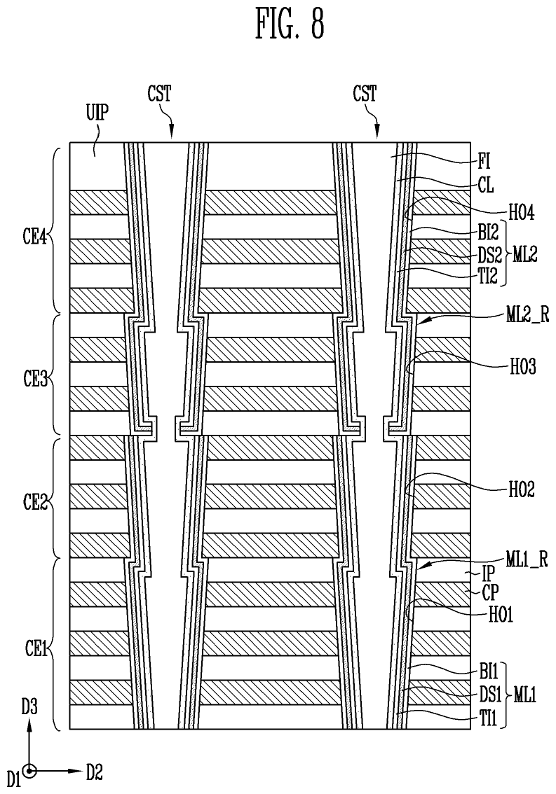

FIG. 8 is a cross-sectional view of a semiconductor memory device according to an embodiment of the present disclosure.

The semiconductor memory device according to the present embodiment is similar to the semiconductor memory device according to FIG. 7 except as described below.

The channel structure CST of the semiconductor memory device according to the present embodiment may include the first memory film ML1 passing through the first stack CE1 and the second stack CE2, and the second memory film ML2 passing through the third stack CE3 and the fourth stack CE4.

The first memory film ML1 may include a first memory film connection portion ML1_R positioned at the boundary between the first and second stacks CE1 and CE2. A width of the first memory film connection portion ML1_R in the second direction D2 between an outer sidewall and an inner sidewall thereof may be greater than a width of the first memory film ML1. The second memory film ML2 may include a second memory film connection portion ML2_R positioned at a boundary between the third and fourth stacks CE3 and CE4. A width of the second memory film connection portion ML2_R in the second direction D2 between an outer sidewall and an inner sidewall thereof may be greater than a width of the second memory film ML2.

The channel film CL may include a first channel connection portion adjacent to the first memory film connection portion ML1_R, a second channel connection portion adjacent to the second memory film connection portion ML2_R, and a channel interposition portion positioned at a boundary between the first and second memory films ML1 and ML2.

A method of manufacturing the semiconductor memory device according to the present embodiment will be described. The first stack CE1 and the first holes HO1 may be formed, the second stack CE2 and the second holes HO2 may be formed, and then the first memory film ML1 may be formed.

The third stack CE3 and the third holes HO3 may be formed, the fourth stack CE4 and the fourth holes HO4 may be formed, and then the second memory film ML2 may be formed.

Subsequently, the channel film CL and the filling film FI passing through the first to fourth stacks CE1, CE2, CE3, and CE4 may be formed.

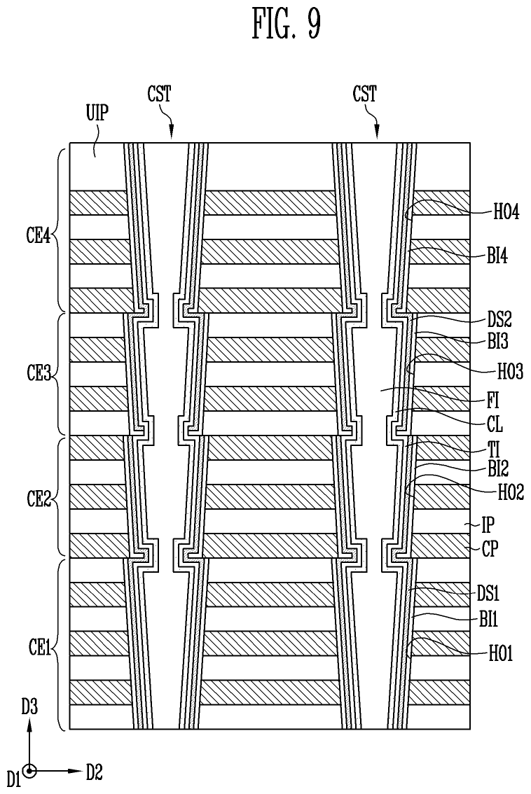

FIG. 9 is a cross-sectional view of a semiconductor memory device according to an embodiment of the present disclosure.

The semiconductor memory device according to the present embodiment is similar to the semiconductor memory device according to FIG. 7 except as described below.

Referring to FIG. 9, the channel structure CST of the semiconductor memory device according to the present embodiment may include a first blocking film BI1 in the first stack CE1, a second blocking film BI2 in the second stack CE2, a third blocking film BI3 in the third stack CE3, and a fourth blocking film BI4 in the fourth stack CE4. Each of the first to fourth blocking films BI1, BI2, BI3, and BI4 may include a blocking pattern portion.

The channel structure CST may have a first storage film DS1 passing through the first and second stacks CE1 and CE2, and a second storage film DS2 passing through the third and fourth stacks CE3 and CE4. Each of the first and second storage films DS1 and DS2 may include storage sidewalls and a storage interposition portion connecting the storage sidewalls to each other. The storage interposition portion may include portions having a width greater than a width of the storage sidewall portions.

The channel structure CST may include a tunnel film TI formed to be a single, continuous element passing through the first to fourth stacks CE1, CE2, CE3, and CE4. The tunnel film TI may include tunnel interposition portions connecting the tunnel sidewall portions to each other. Each of the tunnel interposition portions may include portions having a width greater than a width of the tunnel sidewall portions.

A method of manufacturing the semiconductor memory device according to the present embodiment will be described. The first stack CE1, the first holes HO1, and the first blocking films BI1 may be formed, the second stack CE2, the second holes HO2, and the second blocking films BI2 may be formed, and then the first storage films DS1 may be formed.

The third stack CE3, the third holes HO3, and the third blocking films BI3 may be formed, the fourth stack CE4, the fourth holes HO4, and the fourth blocking films BI4 may be formed, and then the second storage films DS2 may be formed.

Subsequently, the tunnel film TI, the channel film CL, and the filling film FI passing through the first to fourth stacks CE1, CE2, CE3, and CE4 may be formed.

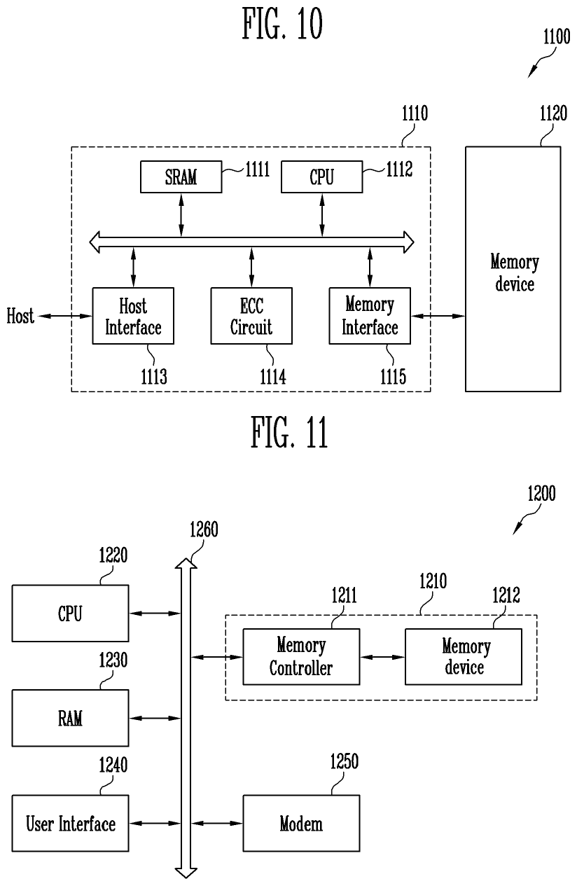

FIG. 10 is a block diagram illustrating a configuration of a memory system according to an embodiment of the present disclosure.

Referring to FIG. 10, the memory system 1100 according to an embodiment of the present disclosure includes a memory device 1120 and a memory controller 1110.

The memory device 1120 may include the structure described with reference to FIGS. 1, 2A and 2B, 4A and 4B, 6A and 6B, 7, 8, or 9. The memory device 1120 may be a multi-chip package configured of a plurality of flash memory chips.

The memory controller 1110 is configured to control the memory device 1120 and may include a static random access memory (SRAM) 1111, a CPU 1112, a host interface 1113, an error correction code circuit (ECC) circuit 1114, and a memory interface 1115. The SRAM 1111 is used as an operation memory of the CPU 1112, the CPU 1112 performs all control operations for data exchange of the memory controller 1110, and the host interface 1113 includes a data exchange protocol of a host connected to the memory system 1100. In addition, the ECC circuit 1114 detects and corrects an error included in data read from the memory device 1120 and the memory interface 1115 performs interfacing with the memory device 1120. In addition, the memory controller 1110 may further include a read only memory (ROM) that stores code data for interfacing with the host.

The memory system 1100 described above may be a memory card or a solid state disk (SSD) with which the memory device 1120 and the memory controller 1110 are combined. For example, when the memory system 1100 is an SSD, the memory controller 1110 may communicate with the outside (for example, a host) through at least one of various interface protocols such as a universal serial bus (USB), a multimedia card (MMC), a peripheral component interconnection-express (PCI-E), a serial advanced technology attachment (SATA), a parallel advanced technology attachment (PATA), a small computer small interface (SCSI), an enhanced small disk interface (ESDI), and integrated drive electronics (IDE).

FIG. 11 is a block diagram illustrating a configuration of a computing system according to an embodiment of the present disclosure.

Referring to FIG. 11, the computing system 1200 according to an embodiment of the present disclosure may include a CPU 1220, a random access memory (RAM) 1230, a user interface 1240, a modem 1250, and a memory system 1210, which are electrically connected to a system bus 1260. In addition, when the computing system 1200 is a mobile device, a battery for supplying an operation voltage to the computing system 1200 may be further included, and an application chipset, a camera image processor (CIS), a mobile DRAM, and the like may be further included.

The memory system 1210 may be configured of the memory device 1212 and the memory controller 1211 as described with reference to FIG. 10. The memory device 1212 may include the structure described with reference to FIGS. 1, 2A and 2B, 4A and 4B, 6A and 6B, 7, 8, or 9.

Although the invention has been described with reference to specific embodiments, the present invention may be practiced according to other embodiments or variations thereof which can be readily envisioned by the skilled person in the art of the present invention, after reading the present disclosure, without departing from the scope and spirit of the invention as defined in the following claims.

What is claimed is:

1. A semiconductor memory device comprising:
a first stack including a first hole;
a second stack provided on the first stack and including a second hole connected to the first hole;
a first memory film formed along an inner sidewall of the first hole;
a second memory film formed along an inner sidewall of the second hole; and
a channel film formed along an inner sidewall of the first memory film and an inner sidewall of the second memory film,
wherein the channel film is a single, continuous element.

2. The semiconductor memory device of claim 1, wherein the channel film comprises:
a first channel sidewall portion formed along the inner sidewall of the first memory film;
a second channel sidewall portion formed along the inner sidewall of the second memory film; and
a channel interposition portion connecting the first and second channel sidewall portions to each other.

3. The semiconductor memory device of claim 2, wherein the channel interposition portion includes a first channel connection portion connected to the second channel sidewall portion, and
a width between an outer sidewall and an inner sidewall of the first channel connection portion is greater than a width of the first and second channel sidewall portions.

4. The semiconductor memory device of claim 3, wherein the channel interposition portion further includes a second channel connection portion connected to the first channel sidewall portion, and
a width between an outer sidewall and an inner sidewall of the second channel connection portion is greater than each of the widths of the first and second channel sidewall portions.

5. The semiconductor memory device of claim 4, wherein the channel interposition portion further includes a third channel connection portion connecting the first channel connection portion and the second channel connection portion, and
a width between an outer sidewall and an inner sidewall of the third channel connection portion is the same as the width of each of the first and second channel sidewall portions.

6. The semiconductor memory device of claim 1, further comprising:
a filling film formed in the channel film,
wherein the filling film is a single, continuous element.

7. The semiconductor memory device of claim 6, wherein the filling film comprises:
a lower portion formed in the first hole;
an upper portion formed in the second hole; and
a filling connection portion connecting the lower portion and the upper portion,
wherein a maximum width of the filling connection portion is smaller than a minimum width of the upper portion.

8. The semiconductor memory device of claim 1, wherein second memory film comprises:
a tunnel film surrounding the channel film;
a storage film surrounding the tunnel film; and
a blocking film surrounding the storage film.

9. The semiconductor memory device of claim 8, wherein the tunnel film includes a tunnel sidewall portion and a tunnel pattern portion, and
a width between an outer sidewall and an inner sidewall of the tunnel pattern portion is greater than a width of the tunnel sidewall portion.

10. The semiconductor memory device of claim 8, wherein the storage film includes a storage sidewall portion and a storage pattern portion, and
a width between an outer sidewall and an inner sidewall of the storage pattern portion is greater than a width of the storage sidewall portion.

11. A semiconductor memory device comprising:
a first stack;
a second stack provided on the first stack;
a first hole passing through the first stack in a vertical direction;
a first blocking film and a first storage film sequentially formed along an inner sidewall of the first hole;
a second hole passing through the second stack in the vertical direction;
a second blocking film and a second storage film sequentially formed along an inner sidewall of the second hole;
a tunnel film formed along an inner sidewall of the first storage film and an inner sidewall of the second storage film; and
a channel film formed in the tunnel film.

12. The semiconductor memory device of claim 11, wherein the first and second blocking films are spaced apart from each other.

13. The semiconductor memory device of claim 11, wherein the first and second storage films are spaced apart from each other.

14. The semiconductor memory device of claim 11, wherein the tunnel film comprises:
a first tunnel sidewall portion formed along the inner sidewall of the first storage film;
a second tunnel sidewall portion formed along the inner sidewall of the second storage film; and
a tunnel interposition portion connecting the first and second tunnel sidewall portions to each other.

15. The semiconductor memory device of claim 14, wherein tunnel interposition portion includes a first tunnel connection portion connected to the second tunnel sidewall portion, and
a width between an outer side surface and an inner side surface of the first tunnel connection portion is greater than a width of each of the first and second tunnel sidewall portions.

16. A method of manufacturing a semiconductor memory device, the method comprising:
forming a first stack including a first hole;
forming a first memory film and a channel sacrificial pattern in the first hole;
forming a second stack including a second hole, on the first stack;
forming a first preliminary memory film along an inner sidewall of the second hole;
removing the channel sacrificial pattern exposed through the second hole; and
forming a channel film in the first hole from which the channel sacrificial pattern is removed, and in the second hole.

17. The method of claim 16, wherein forming the first memory film and the channel sacrificial pattern comprises:
forming a second preliminary memory film along a surface of the first stack;
filling a channel sacrificial film in the first hole in which the second preliminary memory film is formed; and
forming the first memory film and the channel sacrificial pattern by performing a planarization process to expose an upper surface of the first stack.

18. The method of claim 17, wherein the channel sacrificial film has an etching selectivity with respect to the second preliminary memory film.

19. The method of claim 18, wherein the channel sacrificial film includes a metal material of which an etching speed is higher than an etching speed of the second preliminary memory film.

20. The method of claim 16, wherein the channel film is simultaneously formed in the first and second holes.
